(19) United States
(12) Patent Application Publication
(10) Pub. No.: US 2025/0176191 A1
(43) Pub. Date: May 29, 2025

(54) SEMICONDUCTOR DEVICE

(71) Applicant: Samsung Electronics Co., Ltd., Suwon-si (KR)

(72) Inventors: Junhoe KIM, Suwon-si (KR); YONGJAE KIM, Suwon-si (KR); HYUNCHUL SHIN, Suwon-si (KR)

(21) Appl. No.: 18/679,714

(22) Filed: May 31, 2024

(30) Foreign Application Priority Data
Nov. 23, 2023 (KR) 10-2023-0164039

(51) Int. Cl. H10B 61/00

(52) U.S. Cl. CPC H10B 61/00

(57) ABSTRACT

A semiconductor device may include a substrate including a cell region, a peripheral region, and a boundary region therebetween, a first lower insulating layer disposed on the cell region and extending onto the boundary region and the peripheral region, a second lower insulating layer disposed on the first lower insulating layer on the cell region and extending onto the first lower insulating layer on the boundary region and the peripheral region, data storage patterns disposed on the second lower insulating layer on the cell region, a cell insulating layer disposed on the second lower insulating layer on the cell region and the boundary region and covering the data storage patterns, a peripheral insulating layer disposed on the second lower insulating layer on the peripheral region and including a material different from that of the cell insulating layer, and a buffer insulating layer disposed on the cell insulating layer on the boundary region.

### CROSS-REFERENCE TO RELATED APPLICATIONS

This U.S. non-provisional patent application claims priority under 35 U.S.C. § 119 to Korean Patent Application No. 10-2023-0164039 filed on Nov. 23, 2023, in the Korean Intellectual Property Office, the entire content of which is hereby incorporated by reference.

### BACKGROUND OF THE INVENTION

Aspects of the inventive concept relate to a semiconductor device and a method of manufacturing the same, and more specifically, relates to a semiconductor device including a magnetic tunnel junction and a method of manufacturing the same.

High-speed and/or low-voltage semiconductor memory devices have been demanded to realize electronic devices having lower power consumption. Magnetic memory devices have been developed to satisfy these demands. The magnetic memory devices have high-speed operational and/or non-volatile characteristics, so they are spotlighted as a next-generation semiconductor memory device.

Generally, the magnetic memory device may include a magnetic tunnel junction (MTJ) pattern. The MTJ pattern may include two magnetic layers and an insulating layer disposed therebetween. A resistance value of the MTJ pattern may be changed depending on magnetization directions of the two magnetic layers. For example, when the magnetization directions of the two magnetic layers are anti-parallel to each other, the MTJ pattern may have a high resistance value. When the magnetization directions of the two magnetic layers are parallel to each other, the MTJ pattern may have a low resistance value. Data may be written/read using a difference between the high and low resistance values of the MTJ pattern.

In accordance with the diverse needs of the electronics industry, various studies are being conducted on semiconductor devices having an embedded structure in which a magnetic tunnel junction (MTJ) pattern is disposed between metal wirings.

### SUMMARY

An object of the inventive concept is to provide a semiconductor device capable of minimizing defects resulting from a manufacturing process, and a method of manufacturing the same.

An object of the inventive concept is to provide a semiconductor device with improved electrical characteristics and a method of manufacturing the same.

A semiconductor device according to some embodiments of the inventive concept may include a substrate including a cell region, a peripheral region, and a boundary region therebetween, a first lower insulating layer disposed on the cell region and extending onto the boundary region and the peripheral region, a second lower insulating layer disposed on the first lower insulating layer on the cell region and extending onto the first lower insulating layer on the boundary region and the peripheral region, data storage patterns disposed on the second lower insulating layer on the cell region, a cell insulating layer disposed on the second lower insulating layer on the cell region and the boundary region and covering the data storage patterns, a peripheral insulating layer disposed on the second lower insulating layer on the peripheral region and including a material different from that of the cell insulating layer, and a buffer insulating layer disposed on the cell insulating layer on the boundary region.

A semiconductor device according to some embodiments of the inventive concept may include a substrate including a cell region, a peripheral region, and a boundary region therebetween, a first lower insulating layer disposed on the cell region and extending onto the peripheral region, a second lower insulating layer disposed on the first lower insulating layer on the cell region and extending onto the first lower insulating layer on the boundary region and the peripheral region, data storage patterns disposed on the second lower insulating layer on the cell region, lower electrode contacts penetrating the first lower insulating layer and the second lower insulating layer on the cell region and connected to the data storage patterns, respectively, a cell insulating layer disposed on the second lower insulating layer on the cell region and the boundary region and covering the data storage patterns, a peripheral insulating layer disposed on the second lower insulating layer on the peripheral region and including a material different from that of the cell insulating layer, a peripheral conductive contact disposed in the peripheral insulating layer and penetrating the first lower insulating layer and the second lower insulating layer on the peripheral region, and a buffer insulating layer disposed on the cell insulating layer on the boundary region.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a unit memory cell of a semiconductor device according to embodiments of the inventive concept.

FIG. 2 is a plan view of a semiconductor device according to embodiments of the inventive concept.

FIG. 3 is a cross-sectional view taken along line I-I′ of FIG. 2.

FIGS. 4A and 4B are cross-sectional views each illustrating examples of a magnetic tunnel junction pattern of a semiconductor device according to embodiments of the inventive concept.

FIGS. 5 to 10 are diagrams illustrating a method of manufacturing a semiconductor device according to embodiments of the inventive concept, and are cross-sectional views corresponding to line I-I′ of FIG. 2.

FIG. 11 is a cross-sectional view of a semiconductor device according to some embodiments of the inventive concept.

FIG. 12 is a cross-sectional view illustrating a method of manufacturing the semiconductor device of FIG. 11.

### DETAILED DESCRIPTION

Hereinafter, aspects of the inventive concept will be described in detail by explaining embodiments of the inventive concept with reference to the accompanying drawings.

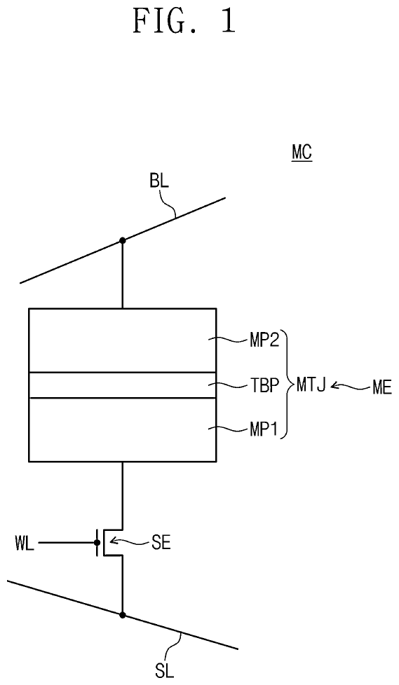

FIG. 1 is a circuit diagram illustrating a unit memory cell of a semiconductor device according to embodiments of the inventive concept.

Referring to FIG. 1, a unit memory cell MC may include a memory element ME and a select element SE. The memory element ME and the select element SE may be electrically connected to each other in series. The memory element ME may be electrically connected between the select element SE and a bit line BL. The select element SE may be connected between the memory element ME and a source line SL, and controlled by a word line WL. The select element SE may include, for example, a bipolar transistor or a MOS field effect transistor.

The memory element ME may include a magnetic tunnel junction MTJ consisting of magnetic patterns MP1 and MP2 spaced apart from each other and a tunnel barrier pattern TBP between the magnetic patterns MP1 and MP2. One of the magnetic patterns MP1 and MP2 may be a reference magnetic patterns having a magnetization direction that is fixed regardless of an external magnetic field under a normal use environment. The other of the magnetic patterns MP1 and MP2 may be a free magnetic patterns whose magnetization direction is freely changed by the external magnetic field. The magnetic tunnel junction MTJ may have an electrical resistance whose value is much greater in the instance in which the magnetization directions of the reference and free magnetic patterns are anti-parallel to each other than in the instance in which the magnetization directions of the reference and free patterns are parallel to each other. That is, the electrical resistance of the magnetic tunnel junction MTJ may be controlled by changing the magnetization direction of the free magnetic pattern. The memory element ME may use the difference in electrical resistance dependent on the magnetization directions of the reference and free magnetic patterns, which mechanism may cause the unit memory cell MC to store data therein.

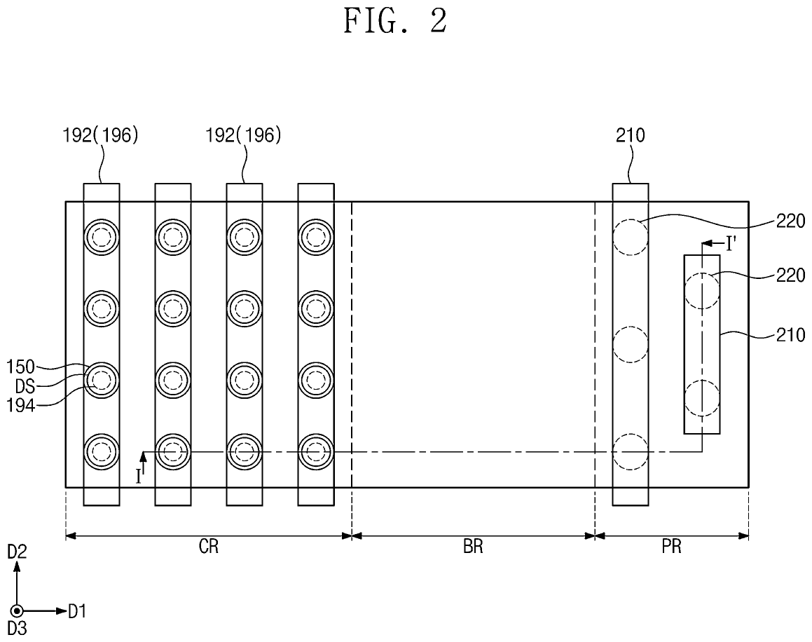

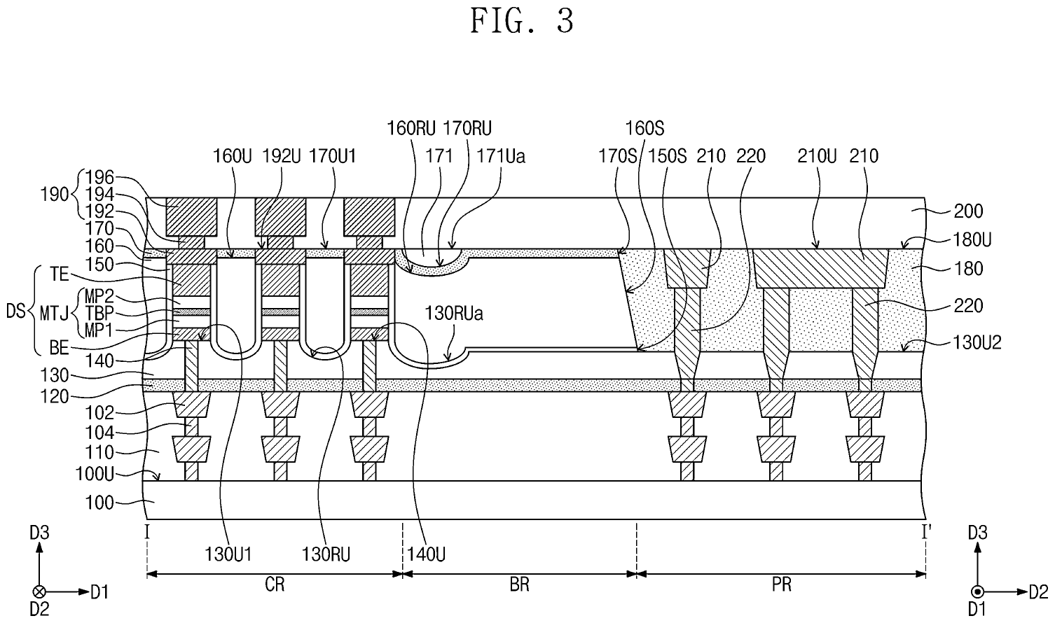

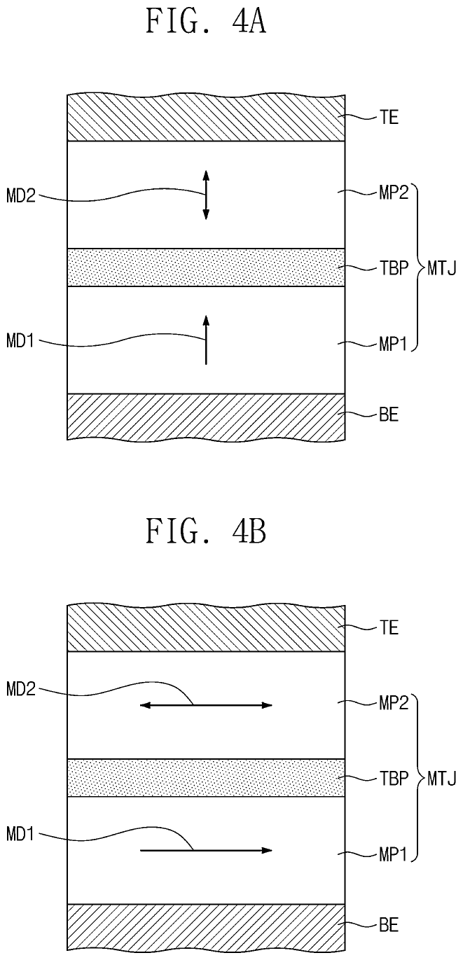

FIG. 2 is a plan view of a semiconductor device according to embodiments of the inventive concept. FIG. 3 is a cross-sectional view taken along line I-I′ of FIG. 2. FIGS. 4A and 4B are cross-sectional views each illustrating examples of a magnetic tunnel junction MTJ pattern of a semiconductor device according to embodiments of the inventive concept.

Referring to FIGS. 2 and 3, a substrate 100 including a cell region CR, a peripheral region PR, and a boundary region BR therebetween may be provided. The substrate 100 may be a semiconductor substrate containing silicon (Si), silicon on insulator (SOI), silicon germanium (SiGe), germanium (Ge), gallium arsenide (GaAs), etc. The cell region CR may be a region of the substrate 100 where the memory cells MC of FIG. 1 are provided, and the peripheral region PR may be another region of the substrate 100 where peripheral circuits for driving the memory cells MC are provided. The boundary region BR may be another region of the substrate 100 provided between the cell region CR and the peripheral region PR.

Wiring structures 102 and 104 may be disposed on the substrate 100. The wiring structures 102 and 104 may be disposed on the cell region CR and the peripheral region PR of the substrate 100. The wiring structures 102 and 104 may include wiring lines 102 vertically spaced from the substrate 100 and wiring contacts 104 connected to the wiring lines 102. The wiring lines 102 may be spaced apart from an upper surface 100U of the substrate 100 in a direction perpendicular to the upper surface 100U of the substrate 100. The wiring contacts 104 may be disposed between the substrate 100 and the wiring lines 102. Each of the wiring lines 102 may be electrically connected to the substrate 100 through a corresponding one of the wiring contacts 104. The wiring lines 102 and wiring contacts 104 may include metal (e.g., copper).

The select elements SE (e.g., see FIG. 1) may be disposed on the cell region CR of the substrate 100, and peripheral transistors constituting peripheral circuits may be disposed on the peripheral region PR of the substrate 100. The select elements and peripheral transistors may be, for example, field effect transistors. Each of the wiring lines 102 may be electrically connected to one terminal of a corresponding one of the select elements (e.g., a source terminal, a drain terminal, or a gate terminal) or one terminal of the peripheral transistors (e.g., a source terminal, a drain terminal, or a gate terminal) through a corresponding one of the wiring contacts 104.

A wiring insulating layer 110 may be disposed on the substrate 100 to cover the wiring structures 102 and 104. The wiring insulating layer 110 may be disposed on the cell region CR of the substrate 100 and may extend onto the boundary region BR and the peripheral region PR of the substrate 100. The wiring insulating layer 110 may expose (i.e., not cover) upper surfaces of the uppermost wiring lines 102 among the wiring lines 102. For example, an upper surface of the wiring insulating layer 110 may be substantially coplanar with the upper surfaces of the uppermost wiring lines 102. The wiring insulating layer 110 may include, for example, silicon oxide, silicon nitride, and/or silicon oxynitride.

A first lower insulating layer 120 may be disposed on the wiring insulating layer 110 and cover the exposed upper surfaces of the uppermost wiring lines 102. The first lower insulating layer 120 may be disposed on the wiring insulating layer 110 on the cell region CR and may extend onto the wiring insulating layer 110 on the boundary region BR and peripheral region PR. The first lower insulating layer 120 may include, for example, silicon oxide, silicon nitride, and/or silicon oxynitride.

A second lower insulating layer 130 may be disposed on the first lower insulating layer 120. The second lower insulating layer 130 may be disposed on the first lower insulating layer 120 on the cell region CR and may extend onto the first lower insulating layer 120 on the boundary region BR and peripheral region PR. The first lower insulating layer 120 may be interposed between the wire insulating layer 110 and the second lower insulating layer 130 in the cell region CR, boundary region BR, and peripheral region PR. The second lower insulating layer 130 may include, for example, silicon oxide, silicon nitride, and/or silicon oxynitride.

The second lower insulating layer 130 may include a material different from that of the first lower insulating layer 120. As an example, the first lower insulating layer 120 may include silicon nitride (e.g., silicon carbon nitride (SiCN)), and the second lower insulating layer 130 may include silicon oxide (e.g., tetrathoxysilane (TEOS) silicon oxides).

Data storage patterns DS may be disposed on the second lower insulating layer 130 on the cell region CR. The data storage patterns DS may be spaced apart from each other in a first direction D1 and a second direction D2 that are parallel to the upper surface 100U of the substrate 100 and intersect each other.

The second lower insulating layer 130 on the cell region CR may have an upper surface 130RU that is recessed toward the substrate 100 between the data storage patterns DS. The recessed upper surface 130RU of the second lower insulating layer 130 on the cell region CR may be positioned at a lower height than the uppermost surface 130U1 of the second lower insulating layer 130 on the cell region CR. In this specification, a height is a distance measured from the upper surface 100U of the substrate 100 in a third direction D3 perpendicular to the upper surface 100U of the substrate 100.

An upper surface 130U2 of the second lower insulating layer 130 on the peripheral region PR may be positioned at a lower height than the uppermost surface 130U1 of the second lower insulating layer 130 on the cell region CR. According to some embodiments, the upper surface 130U2 of the second lower insulating layer 130 on the peripheral region PR may be positioned at a lower height than the recessed upper surface 130RU of the second lower insulating layer 130 on the cell region CR. According to other embodiments, the upper surface 130U2 of the second lower insulating layer 130 on the peripheral region PR may be positioned at the same height as the recessed upper surface 130RU of the second lower insulating layer 130 on the cell region CR. According to still other embodiments, the upper surface 130U2 of the second lower insulating layer 130 on the peripheral region PR may be positioned at a higher height than the height of the recessed upper surface 130RU of the second lower insulating layer 130 on the cell region CR.

The second lower insulating layer 130 on the boundary region BR may have an upper surface 130RUa that is recessed toward the substrate 100. The recessed upper surface 130RUa of the second lower insulating layer 130 on the boundary region BR may be positioned at a lower height than the uppermost surface 130U1 of the second lower insulating layer 130 on the cell region CR. According to some embodiments, the recessed upper surface 130RUa of the second lower insulating layer 130 on the boundary region BR may be positioned at a lower height than the recessed upper surface 130RU of the second lower insulating layer 130 on the cell region CR and may be positioned at a lower height than the upper surface 130U2 of the second lower insulating layer 130 on the peripheral region PR.

Lower electrode contacts 140 may be disposed in the second lower insulating layer 130 on the cell region CR and may be spaced apart from each other in the first direction D1 and the second direction D2. The lower electrode contacts 140 may be respectively disposed below the data storage patterns DS and may be electrically connected to the data storage patterns DS, respectively. Each of the lower electrode contacts 140 may penetrate the first and second lower insulating layers 120 and 130 on the cell region CR and may be connected to a corresponding one of the uppermost wiring lines 102. Each of the data storage patterns DS may be electrically connected to one terminal (e.g., a drain terminal) of the corresponding select element through each of the lower electrode contacts 140 and the corresponding uppermost wiring line 102.

Upper surfaces 140U of the lower electrode contacts 140 may be positioned at a higher height than the recessed upper surface 130RU of the second lower insulating layer 130 on the cell region CR. The upper surfaces 140U of the lower electrode contacts 140 may be positioned at the same height as the uppermost surface 130U1 of the second lower insulating layer 130 on the cell region CR. The recessed upper surface 130RUa of the second lower insulating layer 130 on the boundary region BR and the upper surface 130U2 of the second lower insulating layer 130 on the peripheral region PR may be positioned at a lower height than the upper surfaces 140U of the lower electrode contacts 140.

The lower electrode contacts 140 may include at least one of a doped semiconductor material (e.g., doped silicon), a metal (e.g., tungsten, titanium, and/or tantalum), a metal-semiconductor compound (e.g., metal silicide), and a conductive metal nitride (e.g., titanium nitride, tantalum nitride, and/or tungsten nitride).

Each of the data storage patterns DS may include a lower electrode BE, a magnetic tunnel junction pattern MTJ, and an upper electrode TE that are sequentially stacked on the second lower insulating layer 130 in the third direction D3. The magnetic tunnel junction pattern MTJ may be disposed between the lower electrode BE and the upper electrode TE. Each of the lower electrode contacts 140 may be connected to each lower electrode BE of the data storage patterns DS. Each of the lower electrodes BE of the data storage patterns DS may be in contact with the upper surface 140U of each of the lower electrode contacts 140 and the uppermost surface 130U1 of the second lower insulating layer 130 on the cell region CR. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The magnetic tunnel junction pattern MTJ may include a first magnetic pattern MP1, a second magnetic pattern MP2, and a tunnel barrier pattern TBP therebetween. The first magnetic pattern MP1 may be disposed between the lower electrode BE and the tunnel barrier pattern TBP, and the second magnetic pattern MP2 may be disposed between the upper electrode TE and the tunnel barrier pattern TBP. The lower electrode BE may include, for example, a conductive metal nitride (e.g., titanium nitride or tantalum nitride). The upper electrode TE may include at least one of a metal (e.g., Ta, W, Ru, Ir, etc.) and a conductive metal nitride (e.g., TiN).

Referring to FIGS. 4A and 4B, the first magnetic pattern MP1 may be a reference layer having a magnetization direction MD1 fixed in one direction, and the second magnetic pattern MP2 may be a free layer having a magnetization direction MD2 that is capable of being changed to be parallel or anti-parallel to the magnetization direction MD1 of the first magnetic pattern MP1. FIGS. 4A and 4B each illustrate a case in which the second magnetic pattern MP2 is a free layer as an example, but aspects of the inventive concept are not limited thereto. Unlike FIGS. 4A and 4B, the first magnetic pattern MP1 may be a free layer and the second magnetic pattern MP2 may be a reference layer.

Referring to FIG. 4A, the magnetization directions MD1 and MD2 of the first magnetic pattern MP1 and the second magnetic pattern MP2 may be perpendicular to an interface of the tunnel barrier pattern TBP and the second magnetic pattern MP2. In this case, each of the first magnetic pattern MP1 and the second magnetic pattern MP2 may include at least one of an intrinsic perpendicular magnetic substance and an extrinsic perpendicular magnetic substance. The intrinsic perpendicular magnetic substance may include a material having perpendicular magnetization characteristics even when there is no external factor. The intrinsic perpendicular magnetic substance may include at least one of i) perpendicular magnetic substance (e.g., CoFeTb, CoFeGd, CoFeDy), ii) perpendicular magnetic substance having an L10 structure, iii) CoPt having a hexagonal close packed lattice structure, and iv) vertical magnetic structures. The perpendicular magnetic substance having the L10 structure may include at least one of FePt of L10 structure, FePd of L10 structure, CoPd of L10 structure, or CoPt of L10 structure. The perpendicular magnetic structure may include magnetic layers and non-magnetic layers that are alternately and repeatedly stacked. For example, the perpendicular magnetic structure may include at least one of (Co/Pt) n, (CoFe/Pt) n, (CoFe/Pd) n, (Co/Pd) n, (Co/Ni) n, (CoNi/Pt) n, (CoCr/Pt) n, or (CoCr/Pd) n (‘n’ is the number of stacking). The extrinsic perpendicular magnetic substance may include a material having intrinsic horizontal magnetization characteristics and perpendicular magnetization characteristics due to an external factor. For example, the extrinsic perpendicular magnetic substance may have the perpendicular magnetization characteristics due to magnetic anisotropy induced by making a junction of the first magnetic pattern MP1 (or the second magnetic pattern MP2) and the tunnel barrier pattern TBP. The extrinsic perpendicular magnetic substance may include, for example, CoFeB.

Referring to FIG. 4B, as another example, the magnetization directions MD1 and MD2 of the first magnetic pattern MP1 and the second magnetic pattern MP2 may be parallel to the interface of the tunnel barrier pattern TBP and the second magnetic pattern MP2. In this case, each of the first magnetic pattern MP1 and the second magnetic pattern MP2 may include a ferromagnetic substance. The first magnetic pattern MP1 may further include an antiferromagnetic substance for fixing a magnetization direction of the ferromagnetic substance in the first magnetic pattern MP1.

Each of the first magnetic pattern MP1 and the second magnetic pattern MP2 may include a Co-based Heusler alloy. The tunnel barrier pattern TBP may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer.

Referring again to FIGS. 2 and 3, a capping insulating layer 150 may be disposed on the second lower insulating layer 130 on the cell region CR. The capping insulating layer 150 may conformally cover each side of the data storage patterns DS and the recessed upper surface 130RU of the second lower insulating layer 130 on the cell region CR. The capping insulating layer 150 may surround each side surfaces of the data storage patterns DS when viewed in a plan view. The capping insulating layer 150 may extend onto the second lower insulating layer 130 on the boundary region BR, and may conformally cover the recessed upper surface 130RUa of the second lower insulating layer 130 on the boundary region BR.

The capping insulating layer 150 may conformally cover side surfaces of the lower electrode BE, the magnetic tunnel junction pattern MTJ, and the upper electrode TE. The capping insulating layer 150 may surround the side surfaces of the lower electrode BE, the magnetic tunnel junction pattern MTJ, and the upper electrode TE when viewed in a plan view. The capping insulating layer 150 may include nitride (e.g., silicon nitride).

A cell insulating layer 160 may be disposed on the second lower insulating layer 130 on the cell region CR and cover the data storage patterns DS. The cell insulating layer 160 may fill a space between the data storage patterns DS. The capping insulating layer 150 may be interposed between each side surfaces of the data storage patterns DS and the cell insulating layer 160, and may extend between the recessed upper surface 130RU of the second lower insulating layer 130 on the cell region CR. And the cell insulating layer 160. The cell insulating layer 160 may extend onto the second lower insulating layer 130 on the boundary region BR. The capping insulating layer 150 may extend between the cell insulating layer 160 and the recessed upper surface 130RUa of the second lower insulating layer 130 on the boundary region BR. The cell insulating layer 160 may include, for example, silicon oxide, silicon nitride, and/or silicon oxynitride.

The cell insulating layer 160 on the boundary region BR may have an upper surface 160RU that is recessed toward the substrate 100. The recessed upper surface 160RU of the cell insulating layer 160 on the boundary region BR may be positioned at a lower height than an upper surface 160U of the cell insulating layer 160 on the cell region CR.

An upper insulating layer 170 may be disposed on the cell insulating layer 160 in the cell region CR. The upper insulating layer 170 may extend onto the cell insulating layer 160 on the boundary region BR. The upper insulating layer 170 may include a material different from that of the cell insulating layer 160. As an example, the cell insulating layer 160 may include silicon oxide, and the upper insulating layer 170 may include silicon nitride (e.g., silicon carbon nitride (SiCN)).

The upper insulating layer 170 on the boundary region BR may have an upper surface 170RU that is recessed toward the substrate 100. The recessed upper surface 170RU of the upper insulating layer 170 on the boundary region BR may be positioned at a lower height than the uppermost surface 170U1 of the upper insulating layer 170 on the cell region CR.

A buffer insulating layer 171 may be disposed on the upper insulating layer 170 on the boundary region BR. The buffer insulating layer 171 may be in contact with the recessed upper surface 170RU of the upper insulating layer 170 on the boundary region BR. The upper surface 171Ua of the buffer insulating layer 171 may be positioned at the same height as the uppermost surface 170U1 of the upper insulating layer 170 on the cell region CR.

The buffer insulating layer 171 may include silicon oxide (e.g., tetrathoxysilane (TEOS)).

A peripheral insulating layer 180 may be disposed on the second lower insulating layer 130 in the peripheral region PR. The peripheral insulating layer 180 may be in contact with the upper surface 130U2 of the second lower insulating layer 130 on the peripheral region PR. The peripheral insulating layer 180 may be in contact with a side surface 160S of the cell insulating layer 160 and a side surface 170S of the upper insulating layer 170. The peripheral insulating layer 180 may be in contact with a side surface 150S of the capping insulating layer 150. The peripheral insulating layer 180 may be in contact with a side surface of the buffer insulating layer 171.

For example, an upper surface 180U of the peripheral insulating layer 180 may be positioned at a lower height than the uppermost surface 170U1 of the upper insulating layer 170 on the cell region CR. As another example, although not illustrated, the upper surface 180U of the peripheral insulating layer 180 may be positioned at a higher height than the uppermost surface 170U1 of the upper insulating layer 170 on the cell region CR. Preferably, as shown in FIG. 3, the upper surface 180U of the peripheral insulating layer 180 may be positioned at the same height as the uppermost surface 170U1 of the upper insulating layer 170 on the cell region CR, and may be coplanar with each other. A difference between a height of the upper surface 180U of the peripheral insulating layer 180 and a height of the uppermost surface 170U1 of the upper insulating layer 170 on the cell region CR may be within 15 nm. For example, the upper surface 180U of the peripheral insulating layer 180 may be positioned at a lower height than the upper surface 171Ua of the buffer insulating layer 171 on the boundary region BR. As another example, although not illustrated, the upper surface 180U of the peripheral insulating layer 180 may be positioned at a higher height than the upper surface 171Ua of the buffer insulating layer 171 on the boundary region BR. Preferably, as shown in FIG. 3, the upper surface 180U of the peripheral insulating layer 180 may be positioned at the same height as the upper surface 171Ua of the buffer insulating layer 171 on the boundary region BR. A difference between a height of the upper surface 180U of the peripheral insulating layer 180 and a height of the upper surface 171Ua of the buffer insulating layer 171 on the boundary region BR may be within 15 nm.

The peripheral insulating layer 180 may include a material different from that of the cell insulating layer 160. The peripheral insulating layer 180 may include an insulating material with a lower dielectric constant (k) than that of the cell insulating layer 160. The peripheral insulating layer 180 may include a different material from that of the upper insulating layer 170, and may include an insulating material with a lower dielectric constant (k) than that of the upper insulating layer 170. The peripheral insulating layer 180 may include a material different from that of the second lower insulating layer 130. The peripheral insulating layer 180 may include, for example, silicon oxide, silicon nitride, and/or silicon oxynitride. As an example, the peripheral insulating layer 180 may include an insulating material with a dielectric constant (k) of about 2.5 or less than 2.0, for example, porous SiOC.

First cell conductive lines 192 may be disposed on the cell region CR. The first cell conductive lines 192 may be spaced apart from each other in the first direction D1 and may extend in the second direction D2. Each of the first cell conductive lines 192 may have a line shape extending in the second direction D2. Each of the first cell conductive lines 192 may be electrically connected to corresponding data storage patterns of the data storage patterns DS that are spaced apart from each other in the second direction D2. Among the data storage patterns DS, the data storage patterns DS spaced apart from each other in the first direction D1 may be electrically connected to the first cell conductive lines 192, respectively.

Each of the first cell conductive lines 192 may penetrate the upper insulating layer 170 on the cell region CR, and may penetrate the upper portion of the cell insulating layer 160 and be connected to the corresponding data storage pattern DS. A lower surface of each of the first cell conductive lines 192 may be in contact with the upper electrode TE of the corresponding data storage pattern DS. Upper surfaces 192U of the first cell conductive lines 192 may be positioned at the same height as the uppermost surface 170U1 of the upper insulating layer 170 on the cell region CR and may be coplanar with the uppermost surface 170U1. The first cell conductive lines 192 may include a conductive material, for example, metal (e.g., copper).

Peripheral conductive lines 210 may be disposed on the second lower insulating layer 130 in the peripheral region PR and in the peripheral insulating layer 180. The peripheral insulating layer 180 may cover the peripheral conductive lines 210. The peripheral conductive lines 210 may penetrate an upper portion of the peripheral insulating layer 180. Upper surfaces 210U of the peripheral conductive lines 210 may not covered by the peripheral insulating layer 180. The upper surfaces 210U of the peripheral conductive lines 210 may be positioned at the same height as the upper surface 180U of the peripheral insulating layer 180 and may be coplanar with the upper surface 180U of the peripheral insulating layer 180. For example, although not illustrated, the upper surfaces 210U of the peripheral conductive lines 210 may be positioned at a lower height than the upper surfaces 192U of the first cell conductive lines 192, the uppermost surface 170U1 of the upper insulating layer 170 on the cell region CR, and the upper surface 171Ua of the buffer insulating layer 171. As another example, although not illustrated, the upper surfaces 210U of the peripheral conductive lines 210 may be positioned at a higher height than the upper surfaces 192U of the first cell conductive lines 192, the uppermost surface 170U1 of the upper insulating layer 170 on the cell region CR, and the upper surface 171Ua of the buffer insulating layer 171. Preferably, as shown in FIG. 3, the upper surfaces 210U of the peripheral conductive lines 210 may be the same height as the upper surfaces 192U of the first cell conductive lines 192, the uppermost surface 170U1 of the upper insulating layer 170 on the cell region CR, and the upper surface 171Ua of the buffer insulating layer 171. A difference between a height of the upper surfaces 210U of the peripheral conductive lines 210 and a height of each of the upper surfaces 192U of the first cell conductive lines 192, the uppermost surface 170U1 of the upper insulating layer 170 on the cell region CR, and the upper surface 171Ua of the buffer insulating layer 171 may be within 15 nm.

Peripheral conductive contacts 220 may be disposed on the peripheral region PR and below the peripheral conductive lines 210. The peripheral conductive contacts 220 may be electrically connected to the peripheral conductive lines 210. Each of the peripheral conductive contacts 220 may be in contact with the corresponding peripheral conductive line 210 among the peripheral conductive lines 210 without an interface. Each of the peripheral conductive contacts 220 and the corresponding peripheral conductive line 210 may be connected to each other to form an integrated body. Each of the peripheral conductive contacts 220 may penetrate a lower portion of the peripheral insulating layer 180. Each of the peripheral conductive contacts 220 may penetrate the second lower insulating layer 130 and the first lower insulating layer 120 on the peripheral region PR, and may be electrically connected to a corresponding one of the uppermost wiring lines 102. Each of the peripheral conductive lines 210 may be electrically connected to one terminal (e.g., a source terminal, a drain terminal, or a gate) of the corresponding peripheral transistor through the corresponding peripheral conductive contacts 220 and the corresponding uppermost wiring lines 102.

The peripheral conductive lines 210 and the peripheral conductive contacts 220 may include a conductive material, for example, metal (e.g., copper). The first cell conductive lines 192, peripheral conductive lines 210, and peripheral conductive contacts 220 may include the same material.

An upper interlayer insulating layer 200 may be disposed on the cell region CR, boundary region BR, and peripheral region PR, and may cover the uppermost surface 170U1 of the upper insulating layer 170 on the cell region CR, the upper surface 171Ua of the buffer insulating layer 171, the upper surfaces 192U of the first cell conductive lines 192, the upper surface 180U of the peripheral insulating layer 180, and the upper surfaces 210U of the peripheral conductive lines 210. The upper interlayer insulating layer 200 may include, for example, silicon oxide, silicon nitride, and/or silicon oxynitride.

Second cell conductive lines 196 may be disposed in the upper interlayer insulating layer 200 on the cell region CR. The second cell conductive lines 196 may be spaced apart from each other in the first direction D1 and may extend in the second direction D2. The second cell conductive lines 196 may overlap each of the first cell conductive lines 192 vertically (e.g., in the third direction D3). Conductive contacts 194 may be disposed in the upper interlayer insulating layer 200 on the cell region CR and may be disposed between the first cell conductive lines 192 and the second cell conductive lines 196. Each of the first cell conductive lines 192 may be electrically connected to each of the second cell conductive lines 196 through corresponding conductive contacts 194 of the conductive contacts 194. Each of the first cell conductive lines 192, the corresponding conductive contacts 194, and each of the second cell conductive lines 196 may constitute a bit line 190 (bit line BL in FIG. 1). The conductive contacts 194 and the second cell conductive lines 196 may include a conductive material, for example, metal (e.g., copper).

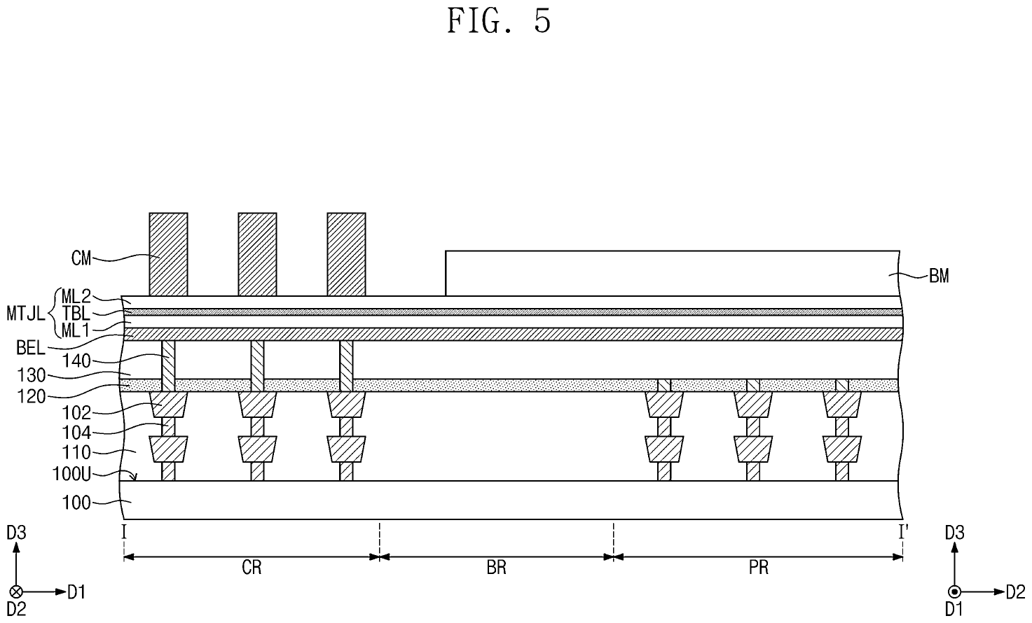

FIGS. 5 to 10 are diagrams illustrating a method of manufacturing a semiconductor device according to embodiments of the inventive concept, and are cross-sectional views corresponding to line I-I′ of FIG. 2. To simplify the description, descriptions that overlap with the semiconductor devices described with reference to FIGS. 1 to 3, 4A, and 4B are omitted.

Referring to FIGS. 2 and 5, a substrate 100 may be provided including a cell region CR, a peripheral region PR, and a boundary region BR therebetween. The select elements SE (e.g., see FIG. 1) and peripheral transistors may be formed on the substrate 100, and wiring structures 102 and 104 may be formed on the select elements SE and peripheral transistors. The wiring structures 102 and 104 include wiring lines 102 spaced vertically (e.g., in the third direction D3) from the substrate 100, and wiring contacts 104 connected to the wiring lines 102. Each of the wiring lines 102 may be connected to one terminal of a corresponding one of the select elements (e.g., a source terminal, a drain terminal, or a gate terminal) or a terminal (e.g., a source terminal, a drain terminal, or a gate terminal) of the peripheral transistors through a corresponding one of the wiring contacts 104.

A wiring insulating layer 110 may be formed on the substrate 100 and cover the wiring structures 102 and 104. The wiring insulating layer 110 may expose (i.e., not cover) upper surfaces of the uppermost wiring lines 102 among the wiring lines 102.

A first lower insulating layer 120 may be formed on the wiring insulating layer 110 and cover the exposed upper surfaces of the uppermost wiring lines 102. The first lower insulating layer 120 may be formed on the wiring insulating layer 110 on the cell region CR, and may extend onto the wiring insulating layer 110 on the boundary region BR and peripheral region PR.

A second lower insulating layer 130 may be formed on the first lower insulating layer 120. The second lower insulating layer 130 may be formed on the first lower insulating layer 120 on the cell region CR, and may extend onto the first lower insulating layer 120 on the boundary region BR and peripheral region PR.

Lower electrode contacts 140 may be formed in the second lower insulating layer 130 on the cell region CR. Each of the lower electrode contacts 140 may penetrate the first and second lower insulating layers 120 and 130 on the cell region CR and may be electrically connected to one of the uppermost wiring lines 102. Forming the lower electrode contacts 140 includes, for example, forming lower contact holes penetrating the first and second lower insulating layers 120 and 130 on the cell region CR, forming a lower contact layer to fill the lower contact holes on the second lower insulating layer 130, and planarizing the lower contact layer until an upper surface of the second lower insulating layer 130 is exposed. Through the planarization process, the lower electrode contacts 140 may be formed locally in each of the lower contact holes.

A lower electrode layer BEL and a magnetic tunnel junction layer MTJL may be sequentially stacked on the second lower insulating layer 130. The lower electrode layer BEL and the magnetic tunnel junction layer MTJL may be formed on the second lower insulating layer 130 on the cell region CR, and may extend on the second lower insulating layer 130 on the boundary region BR and peripheral region PR. The magnetic tunnel junction layer MTJL may include a first magnetic layer ML1, a tunnel barrier layer TBL, and a second magnetic layer ML2 sequentially stacked on the lower electrode layer BEL. For example, the magnetic tunnel junction layer MTJL and the lower electrode layer BEL may be formed through sputtering, chemical vapor deposition, or atomic layer deposition.

Conductive mask patterns CM may be formed on the magnetic tunnel junction layer MTJL on the cell region CR. The conductive mask patterns CM may define a region where magnetic tunnel junction patterns MTJ, which will be described later, will be formed. The conductive mask patterns CM may be spaced apart from each other in the first direction D1 and the second direction D2 on the magnetic tunnel junction layer MTJL, and may be formed of metal (e.g., Ta, W, Ru, Ir, etc.) and a conductive metal nitride (e.g., TiN).

A blocking mask pattern BM may be formed on the magnetic tunnel junction layer MTJL in the peripheral region PR. The blocking mask pattern BM may cover the magnetic tunnel junction layer MTJL on the peripheral region PR and may expose (i.e., not cover) the magnetic tunnel junction layer MTJL on the boundary region BR. The blocking mask pattern BM may include, for example, silicon nitride and/or metal nitride.

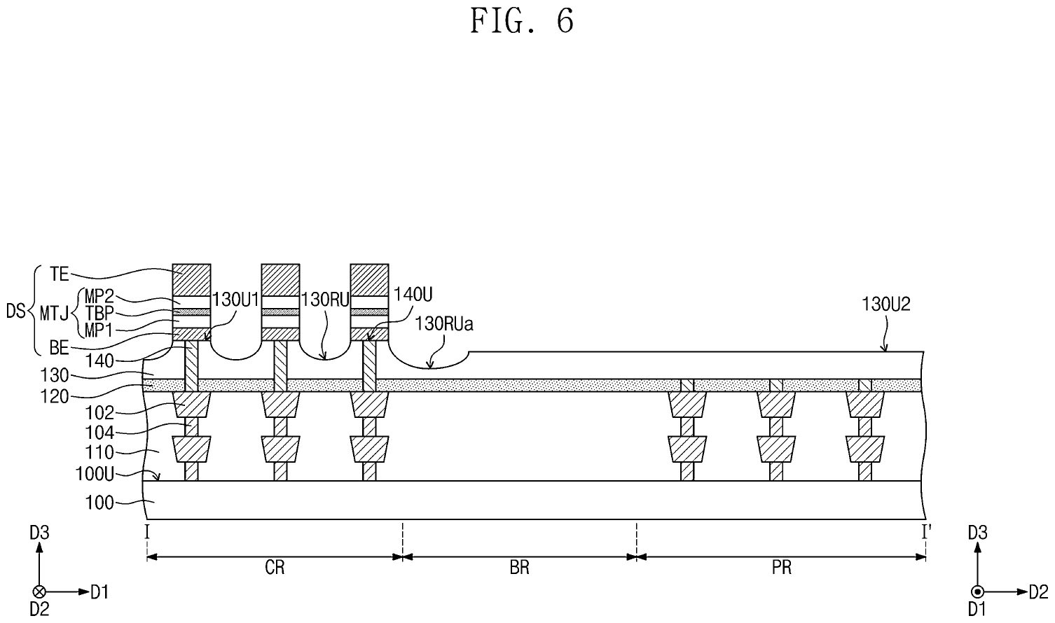

Referring to FIGS. 2 and 6, a first etching process may be performed to etch the magnetic tunnel junction layer MTJL and the lower electrode layer BEL using the conductive mask patterns CM as an etch mask. For example, the first etching process may be an ion beam etching process using an ion beam. The ion beam may include inert ions. The magnetic tunnel junction layer MTJL and the lower electrode layer BEL may be etched to form the magnetic tunnel junction pattern MTJ and the lower electrode BE, respectively.

Etching the magnetic tunnel junction layer MTJL may include sequentially etching the second magnetic layer ML2, the tunnel barrier layer TBL, and the first magnetic layer ML1. The second magnetic layer ML2, the tunnel barrier layer TBL, and the first magnetic layer ML1 may be etched to form the second magnetic pattern MP2, the tunnel barrier pattern TBP, and the first magnetic pattern MP1, respectively. The remainder of the conductive mask pattern CM remaining on the magnetic tunnel junction pattern MTJ after the first etching process may be referred to as an upper electrode TE. The lower electrode BE, magnetic tunnel junction pattern MTJ, and upper electrode TE may be referred to as a data storage pattern DS. A plurality of data storage patterns DS may be formed on the lower electrode contacts 140 and may be spaced apart from each other in the first direction D1 and the second direction D2.

Through the first etching process, an upper portion of the second lower insulating layer 130 between the plurality of data storage patterns DS may be recessed. Accordingly, the second lower insulating layer 130 on the cell region CR may have a upper surface 130RU that is recessed toward the substrate 100. The recessed upper surface 130RU of the second lower insulating layer 130 on the cell region CR may be positioned at a lower height than upper surfaces 140U of the lower electrode contacts 140, and may be positioned at a lower height than the uppermost surface 130U1 of the second lower insulating layer 130. The uppermost surface 130U1 of the second lower insulating layer 130 on the cell region CR may be positioned at the same height as upper surfaces 140U of the lower electrode contacts 140.

The blocking mask pattern BM may be removed during the first etching process, and the magnetic tunnel junction layer MTJL and lower electrode layer BEL on the boundary region BR and peripheral region PR may also be removed during the first etching process. In addition, an upper portion of the second lower insulating layer 130 on the boundary region BR and peripheral region PR may be recessed through the first etching process.

An upper surface 130U2 of the second lower insulating layer 130 on the peripheral region PR may be positioned at a lower height than the uppermost surface 130U1 of the second lower insulating layer 130 on the cell region CR. A thickness of the blocking mask pattern BM (e.g., a thickness in the third direction D3) may be adjusted, and thus the upper surface 130U2 of the second lower insulating layer 130 on the peripheral region PR may be controlled to be positioned at a higher or lower height than the recessed upper surface 130RU of the second lower insulating layer 130 on the cell region CR, and may be controlled to be positioned at the same as the recessed upper surface 130RU of the second lower insulating layer 130 on the cell region CR.

The recessed upper surface 130RUa of the second lower insulating layer 130 on the boundary region BR may be positioned at a lower height than the uppermost surface 130U1 of the second lower insulating layer 130 on the cell region CR. The blocking mask pattern BM may not be provided on the boundary region BR, and accordingly, the recessed upper surface 130RUa of the second lower insulating layer 130 on the boundary region BR may be positioned at a lower height than the recessed upper surface 130U of the second lower insulating layer 130 on the cell region CR and the upper surface 130U2 of the second lower insulating layer 130 on the peripheral region PR.

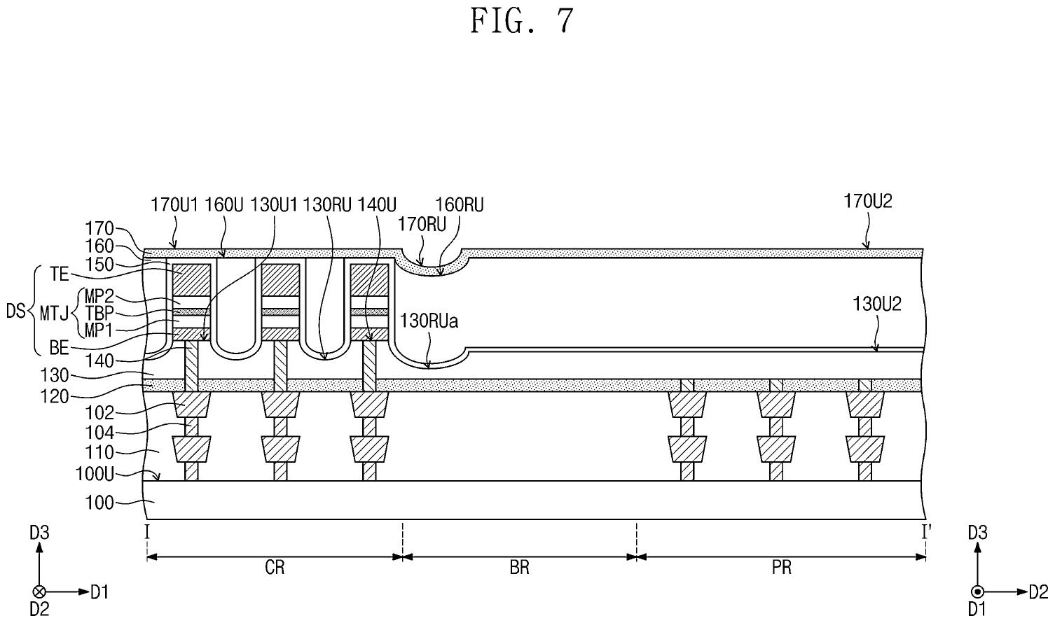

Referring to FIGS. 2 and 7, a capping insulating layer 150 may be formed on the second lower insulating layer 130 on the cell region CR, and may conformally cover upper and side surfaces of each of the data storage patterns DS. The capping insulating layer 150 may conformally cover the recessed upper surface 130RU of the second lower insulating layer 130 on the cell region CR. The capping insulating layer 150 may extend onto the second lower insulating layer 130 on the boundary region BR, and may conformally cover the recessed upper surface 130RUa of the second lower insulating layer 130 on the boundary region BR. The capping insulating layer 150 may extend onto the second lower insulating layer 130 on the peripheral region PR and may cover the upper surface 130U2 of the second lower insulating layer 130 on the peripheral region PR.

A cell insulating layer 160 may be formed on the capping insulating layer 150. The cell insulating layer 160 may be formed on the capping insulating layer 150 on the cell region CR to cover the data storage patterns DS and to fill the space between the data storage patterns DS. The cell insulating layer 160 may extend onto the capping insulating layer 150 on the boundary region BR and peripheral region PR. The cell insulating layer 160 may have a upper surface 160RU that is recessed toward the substrate 100 on the boundary region BR. The recessed upper surface 160RU of the cell insulating layer 160 on the boundary region BR may be positioned at a lower height than the upper surface 160U of the cell insulating layer 160 on the cell region CR. For example, the cell insulating layer 160 may be formed using a high density plasma chemical vapor deposition (HDP CVD) process.

An upper insulating layer 170 may be formed on the cell insulating layer 160 and the capping insulating layer 150. The upper insulating layer 170 may be formed on the cell insulating layer 160 and the capping insulating layer 150 on the cell region CR, and may extend onto the cell insulating layer 160 on the boundary region BR and peripheral region PR. The upper insulating layer 170 on the boundary region BR may have a upper surface 170RU that is recessed toward the substrate 100. The recessed upper surface 170RU of the upper insulating layer 170 on the boundary region BR may be positioned at a lower height than the uppermost surface 170U1 of the upper insulating layer 170 on the cell region CR. The recessed upper surface 170RU of the upper insulating layer 170 on the boundary region BR may be positioned at a lower height than the upper surface 170U2 of the upper insulating layer 170 on the peripheral region PR.

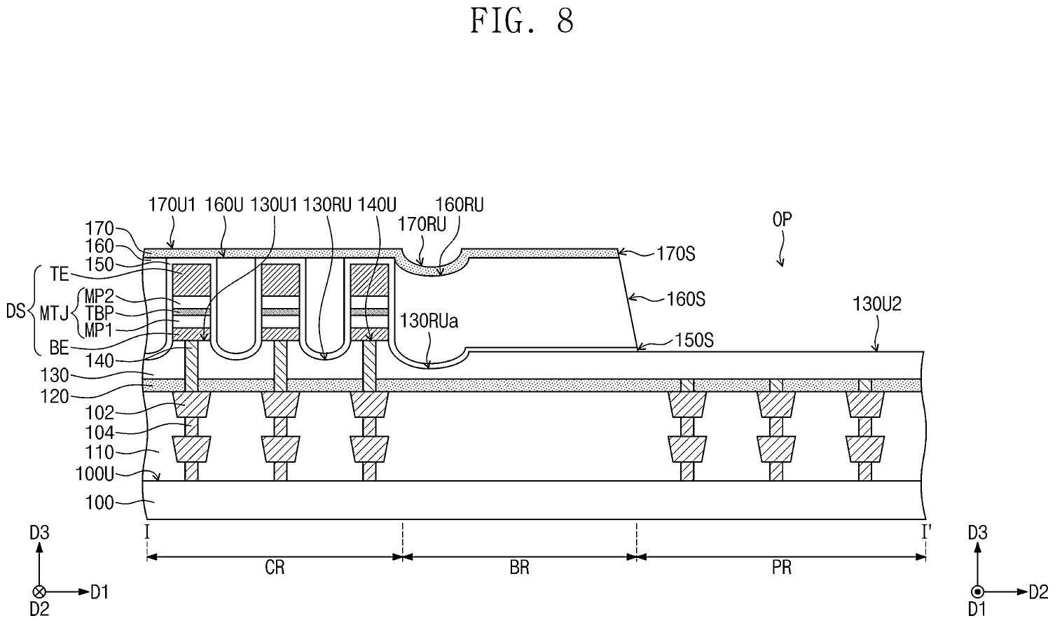

Referring to FIGS. 2 and 8, a peripheral opening OP may be formed on the peripheral region PR and may expose the upper surface 130U2 of the second lower insulating layer 130 on the peripheral region PR. The peripheral opening OP may expose a side surface 170S of the upper insulating layer 170, a side surface 160S of the cell insulating layer 160, and a side surface 150S of the capping insulating layer 150 on the boundary region BR.

Forming the peripheral opening OP may include performing a second etching process to remove the upper insulating layer 170, the cell insulating layer 160, and the capping insulating layer 150 on the peripheral region PR. For example, forming the peripheral opening OP may include forming a cell mask pattern on the upper insulating layer 170 on the cell region CR, and performing the second etch process using the cell mask pattern as an etch mask. For example, the cell mask pattern may be a photoresist pattern. As the upper insulating layer 170, cell insulating layer 160, and capping insulating layer 150 on the peripheral region PR may be removed by the second etching process, and thus the upper surface 130U2 of the second lower insulating layer 130 on the peripheral region PR may be exposed, and the side surface 170S of the upper insulating layer 170, the side surface 160S of the cell insulating layer 160, and the side surface 150S of the capping insulating layer 150 may be exposed on the boundary region BR.

As the second lower insulating layer 130 on the peripheral region PR is not removed during the second etching process, the first lower insulating layer 120 and the uppermost wiring lines 102 on the peripheral region PR on the peripheral region PR may be prevented from being recessed by the second etching process.

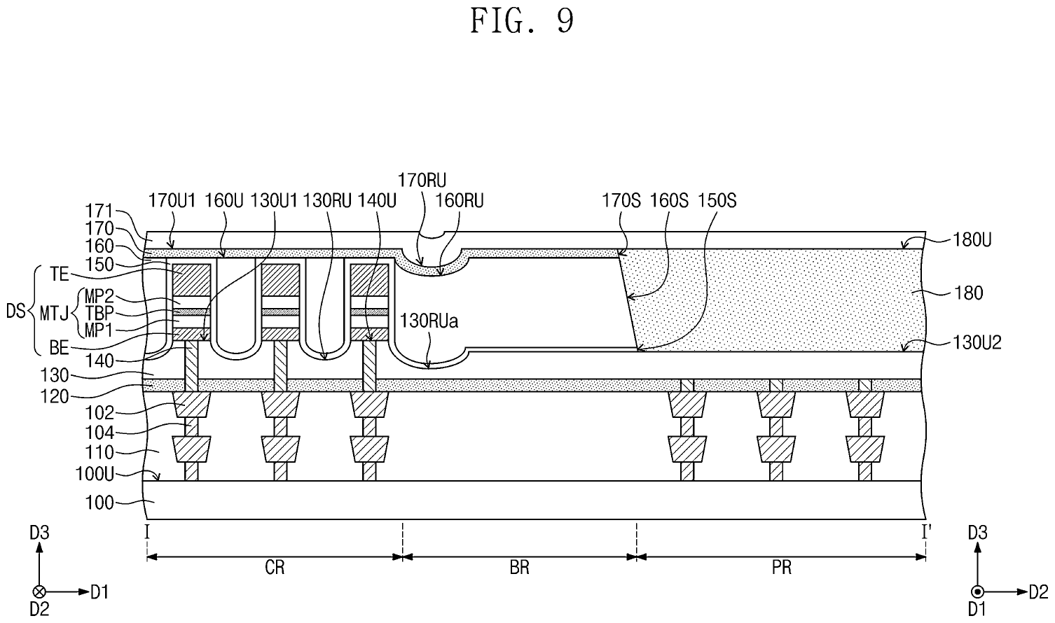

Referring to FIGS. 2 and 9, a peripheral insulating layer 180 may be formed to fill the peripheral opening OP. The peripheral insulating layer 180 may be in contact with the upper surface 130U2 of the second lower insulating layer 130 on the peripheral region PR and may be in contact with the side surface 150S of the capping insulating layer 150, the side surface 160S of the cell insulating layer 160, and the side surface 170S of the upper insulating layer 170 on the boundary region BR. Although not illustrated, forming the peripheral insulating layer 180 may include, for example, filling the peripheral opening OP, forming an insulating layer on the upper insulating layer 170 on the cell region CR and the boundary region BR, and planarizing the insulating layer until the uppermost surface 170U1 of the upper insulating layer 170 on the region CR is exposed. For example, the insulating layer may be formed using a chemical vapor deposition process. For example, the planarization process may be performed using at least one of an etch-back process and a chemical mechanical polishing process. The insulating layer may include a material different from that of the upper insulating layer 170. As an example, the upper insulating layer 170 may include silicon nitride (e.g., silicon carbon nitride (SiCN)), and the insulating layer may include porous silicon oxycarbide (SiOC). In this case, differences in etch rates may occur during the planarization process. For example, an etch rate of the insulating layer may be greater than that of the upper insulating layer 170. Accordingly, when planarizing until the uppermost surface 170U1 of the upper insulating layer 170 on the cell region CR is exposed, the insulating layer formed on the recessed upper surface 170RU of the upper insulating layer 170 on the boundary region BR may also be removed. Accordingly, although not illustrated, the upper surface 180U of the peripheral insulating layer 180 on the peripheral region PR may be positioned at a lower height than the uppermost surface 170U1 of the upper insulating layer 170 on the cell region CR. As another example, although not illustrated, due to a difference in etch rate, the upper surface 180U of the peripheral insulating layer 180 may be positioned at a higher height than the uppermost surface 170U1 of the upper insulating layer 170 on the cell region CR. Preferably, as illustrated in FIG. 9, for example, the upper surface 180U of the peripheral insulating layer 180 may be positioned at the same height as the uppermost surface 170U1 of the upper insulating layer 170 on the cell region CR.

A buffer insulating layer 171 may be formed on the upper insulating layer 170 on the cell region CR and the boundary region BR. The buffer insulating layer 171 may extend onto the peripheral insulating layer 180 in the peripheral region PR. For example, the buffer insulating layer 171 may be formed through a chemical vapor deposition, sputtering, or atomic layer deposition process. The buffer insulating layer 171 may be in contact with the recessed upper surface 170RU of the upper insulating layer 170 on the boundary region BR.

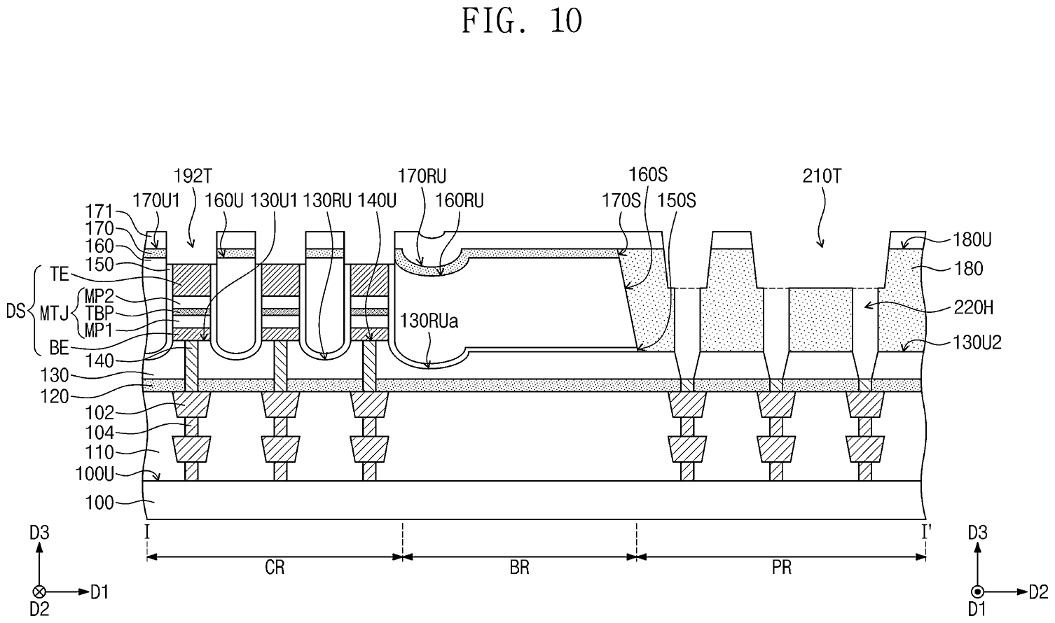

Referring to FIGS. 2 and 10, first cell trenches 192T may be formed in the cell region CR. The first cell trenches 192T may be spaced apart from each other in the first direction D1 and may extend in the second direction D2. Each of the first cell trenches 192T may have a line shape extending in the second direction D2, and may expose corresponding data storage patterns DS spaced apart from each other in the second direction among the data storage patterns DS. Each of the first cell trenches 192T may penetrate the buffer insulating layer 171 and the upper insulating layer 170, and may penetrate the upper portion of the cell insulating layer 160. Each of the first cell trenches 192T may expose each upper electrode TE of the corresponding data storage patterns DS.

Peripheral trenches 210T may be formed on the peripheral region PR and in the buffer insulating layer 171 and the peripheral insulating layer 180. Each of the peripheral trenches 210T may penetrate an upper portion of each of the buffer insulating layer 171 and the peripheral insulating layer 180. Peripheral holes 220H may extend from bottom surfaces of the peripheral trenches 210T toward the substrate 100. Each of the peripheral holes 220H may penetrate a lower portion of the peripheral insulating layer 180 and may penetrate the second lower insulating layer 130 and the first lower insulating layer 120 on the peripheral region PR. Each of the peripheral holes 220H may expose an upper surface of the corresponding wiring line 102 among the uppermost wiring lines 102.

The second lower insulating layer 130 may include a material different from that of the first lower insulating layer 120 and the peripheral insulating layer 180, and accordingly, during the etching process to form the peripheral holes 220H, the etch rate of the second lower insulating layer 130 may be different from the etch rate of the first lower insulating layer 120 and the peripheral insulating layer 180. Accordingly, a width of a portion penetrating the second lower insulating layer 130 of each of the peripheral holes 220H in the horizontal directions D1 and D2 may increase as a distance from the upper surface 100U of the substrate 100 increases.

Referring again to FIGS. 2 and 3, first cell conductive lines 192 may be formed in the cell trenches 192T, respectively. Peripheral conductive lines 210 may be formed in each of the peripheral trenches 210T, and peripheral conductive contacts 220 may be formed in each of the peripheral holes 220H. Forming the first cell conductive lines 192, the peripheral conductive lines 210, and the peripheral conductive contacts 220 may include, for example, forming a conductive layer to fill the cell trenches 192T, the peripheral trenches 210T, and the peripheral holes 220H on the buffer insulating layer 171, the upper insulating layer 170, and the peripheral insulating layer 180, and planarizing the conductive layer until the upper surface 170U1 of the upper insulating layer 170 on the cell region CR, the upper surface 171Ua of the buffer insulating layer 171 on the boundary region BR, and the upper surface 180U of the peripheral insulating layer 180 are exposed. In the planarization process, the buffer insulating layer 171 on the cell region CR and the peripheral region PR may be removed, and the remainder of the buffer insulating layer 171 may remain on the boundary region BR.

A semiconductor device having an embedded structure in which a magnetic tunnel junction pattern MTJ is disposed between metal wirings may include heterogeneous layer materials in the cell region CR and peripheral region PR. In this case, when performing a chemical mechanical planarization process (CMP), a step may occur between the cell region CR and the peripheral region PR due to the difference in the etch rates. Due to defects resulting therefrom, electrical characteristics and reliability of the semiconductor device may deteriorate.

According to the concept of the inventive concept, as described above with reference to FIG. 9, the buffer insulating layer 171 may be formed on the upper insulating layer 170 on the cell region CR and the boundary region BR, and may extend onto the peripheral insulating layer 180 on the peripheral region. Accordingly, in the process of planarizing the conductive layer utilized to form the first cell conductive lines 192, the peripheral conductive lines 210, and the peripheral conductive contacts 220, the buffer insulating layer 171 may also be planarized. Due to the buffer insulating layer 171, a level difference that occurs due to the difference in the etch rates due to the different layer materials between the cell region CR and the peripheral region PR during the planarization process may be reduced. Accordingly, the electrical characteristics and reliability of the semiconductor device may be improved. Preferably, the upper surfaces 192U of the first cell conductive lines 192, the uppermost surface 170U1 of the upper insulating layer 170 on the cell region CR, the upper surface 171Ua of the buffer insulating layer 171 on the boundary region BR, the upper surface 180U of the peripheral insulating layer 180, and the upper surfaces 210U of the peripheral conductive lines 210 may be positioned at the same height.

The upper interlayer insulating layer 200 may be formed on the cell region CR, boundary region BR, and peripheral region PR, and may cover the uppermost surface 170U1 of the upper insulating layer 170 on the cell region CR, the upper surfaces 192U of the first cell conductive lines 192, the upper surface 171Ua of the buffer insulating layer 171 on the boundary region BR, the upper surface 180U of the peripheral insulating layer 180, and the upper surfaces 210U of the peripheral conductive lines 210.

The second cell conductive lines 196 and the conductive contacts 194 may be formed in the upper interlayer insulating layer 200. Forming the second cell conductive lines 196 and the conductive contacts 194 may include, for example, forming second cell trenches penetrating an upper portion of the upper interlayer insulating layer 200, forming contact holes penetrating a lower portion of the upper interlayer insulating layer 200 from a bottom surface of each of the second cell trenches, forming a conductive layer filling the second cell trenches and contact holes on the upper interlayer insulating layer 200, and planarizing the conductive layer until the upper surface of the upper interlayer insulating layer 200.

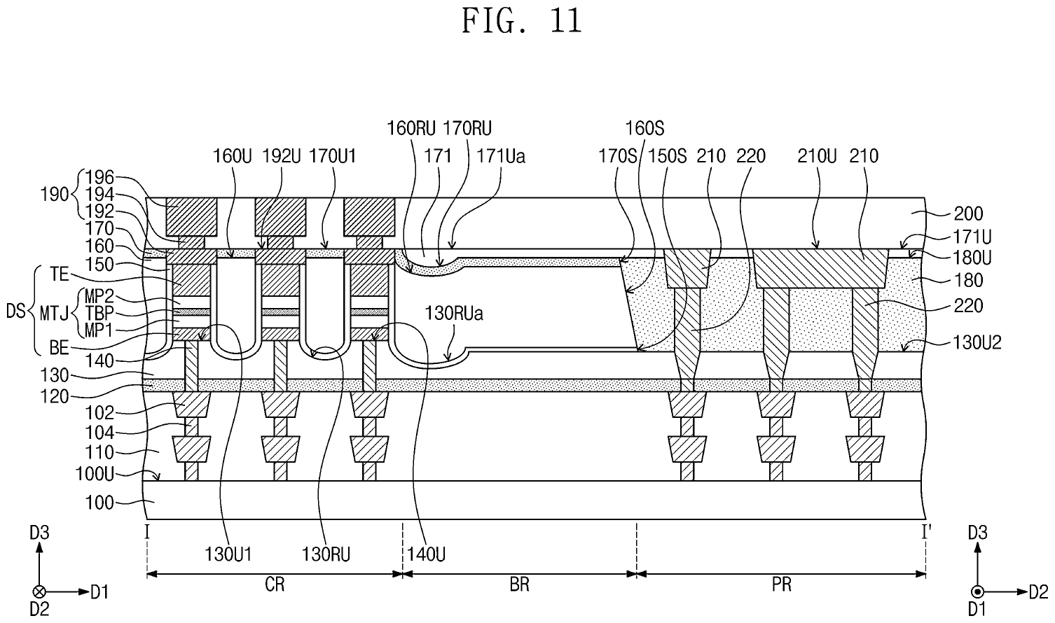

FIG. 11 is a cross-sectional view of a semiconductor device according to some embodiments of the inventive concept. For simplicity of explanation, content that overlaps with the above-described content is omitted.

Referring to FIGS. 2 and 11, the peripheral insulating layer 180 may be disposed on the second lower insulating layer 130 in the peripheral region PR. The peripheral insulating layer 180 may be in contact with the upper surface 130U2 of the second lower insulating layer 130 on the peripheral region PR. The peripheral insulating layer 180 may be in contact with the side surface 160S of the cell insulating layer 160 and the side surface 170S of the upper insulating layer 170. The peripheral insulating layer 180 may be in contact with the side surface 150S of the capping insulating layer 150.

A buffer insulating layer 171 may be disposed on the upper insulating layer 170 on the boundary region BR. The buffer insulating layer 171 may extend onto the peripheral insulating layer 180 in the peripheral region PR. The buffer insulating layer 171 may be in contact with the recessed upper surface 170RU of the upper insulating layer 170 on the boundary region BR. The upper surface 171Ua of the buffer insulating layer 171 on the boundary region BR may be positioned at the same height as the upper surface 171U of the buffer insulating layer 171 on the peripheral region PR. Although not illustrated, the upper surface 171Ua of the buffer insulating layer 171 on the boundary region BR and the upper surface 171U of the buffer insulating layer 171 on the peripheral region PR, for example, may be positioned at a lower height than the uppermost surface 170U1 of the upper insulating layer 170 on the cell region CR. As another example, although not illustrated, the upper surface 171Ua of the buffer insulating layer 171 on the boundary region BR and the upper surface 171U of the buffer insulating layer 171 on the peripheral region PR may be positioned at a higher height than the uppermost surface 170U1 of the upper insulating layer 170 on the cell region CR. Preferably, as shown in FIG. 11, the upper surface 171Ua of the buffer insulating layer 171 on the boundary region BR and the upper surface 171U of the buffer insulating layer 171 on the peripheral region PR may be positioned at the same height as the uppermost surface 170U1 of the upper insulating layer 170 on the cell region CR, and may be coplanar with each other. A difference between a height of the upper surface 171Ua of the buffer insulating layer 171 on the boundary region BR and a height of the uppermost surface 170U1 of the upper insulating layer 170 on the cell region CR may be within 15 nm.

Peripheral conductive lines 210 may be disposed on the second lower insulating layer 130 on the peripheral region PR, and in the peripheral insulating layer 180 and the buffer insulating layer 171 on the peripheral region PR. The peripheral insulating layer 180 and the buffer insulating layer 171 on the peripheral region PR may cover the peripheral conductive lines 210. The peripheral conductive lines 210 may penetrate the buffer insulating layer 171 on the peripheral region PR and an upper portion of the peripheral insulating layer 180. Upper surfaces 210U of the peripheral conductive lines 210 may be exposed without being covered by the buffer insulating layer 171. The upper surfaces 210U of the peripheral conductive lines 210 may be positioned at the same height as the upper surface 171U of the buffer insulating layer 171 on the peripheral region PR. Although not illustrated, the upper surfaces 210U of the peripheral conductive lines 210 may be positioned at a lower height than the upper surfaces 192U of the first cell conductive lines 192. As another example, although not illustrated, the upper surfaces 210U of the peripheral conductive lines 210 may be positioned at a higher height than the upper surfaces 192U of the first cell conductive lines 192. Preferably, as shown in FIG. 11, the upper surfaces 210U of the peripheral conductive lines 210 may be positioned at the same height as the upper surfaces 192U of the first cell conductive lines 192, and may be coplanar with each other. A difference between heights of the upper surfaces 210U of the peripheral conductive lines 210 and heights of the upper surfaces 192U of the first cell conductive lines 192 may be within 15 nm.

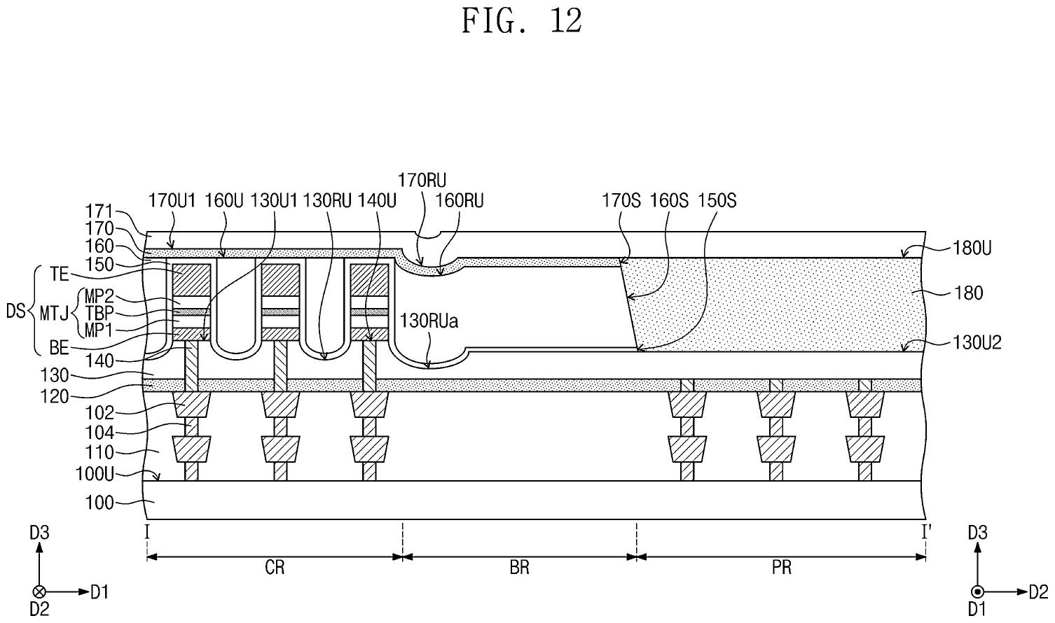

The upper interlayer insulating layer 200 may be disposed on the cell region CR, boundary region BR, and peripheral region PR, and may cover the uppermost surface 170U1 of the upper insulating layer 170 on the cell region CR, the upper surface 171Ua of the buffer insulating layer 171 on the boundary region BR, the upper surface 171U of the buffer insulating layer 171 on the peripheral region BR, the upper surfaces 192U of the first cell conductive lines 192, and the upper surfaces 210U of the peripheral conductive lines 210 may be covered. FIG. 12 is a cross-sectional view illustrating a method of manufacturing the semiconductor device of FIG. 11. To simplify explanation, content that overlaps with the above content is omitted.

Referring to FIGS. 2 and 12, the peripheral insulating layer 180 may be formed to fill the peripheral opening OP. The peripheral insulating layer 180 may be in contact with the upper surface 130U2 of the second lower insulating layer 130 on the peripheral region PR, and may be in contact with the side surface 150S of the capping insulating layer 150, the side surface 160S of the cell insulating layer 160, and the side surface 170S of the upper insulating layer 170 on the boundary region BR. Forming the peripheral insulating layer 180 may include, for example, filling the peripheral opening OP, forming an insulating layer on the upper insulating layer 170 on the cell region CR and the boundary region BR, and planarizing the insulating layer until the uppermost surface 170U1 of the upper insulating layer 170 on the region CR is exposed. For example, the insulating layer may be formed using a chemical vapor deposition process. For example, the planarization process may be performed using at least one of an etch-back process and a chemical mechanical polishing process. The upper surface 180U of the peripheral insulating layer 180 on the peripheral region PR may be positioned at a lower height than the upper surface 170U1 of the upper insulating layer 170 on the cell region CR.

A buffer insulating layer 171 may be formed on the upper insulating layer 170 on the cell region CR and the boundary region BR. The buffer insulating layer 171 may extend onto the peripheral insulating layer 180 in the peripheral region PR. For example, the buffer insulating layer 171 may be formed through a chemical vapor deposition, sputtering, or atomic layer deposition process.

As a subsequent process, the first cell conductive lines 192 and peripheral conductive lines 210 may be formed through substantially the same process as described above with reference to FIGS. 10 and 3. However, after forming the conductive layer, in the process of planarizing the conductive layer until the uppermost surface 170U1 of the upper insulating layer 170 on the cell region CR is exposed, all of the buffer insulating layer 171 on the peripheral region PR may not be removed. The upper surface 180U of the peripheral insulating layer 180 on the peripheral region PR may be positioned at a lower height than the uppermost surface 170U1 of the upper insulating layer 170 on the cell region CR, even if all the buffer insulating layer 171 on the cell region CR is removed, the buffer insulating layer 171 on the peripheral region PR may remain.

According to the concept of the inventive concept, the buffer insulating layer 171 may be formed on the upper insulating layer 170 on the cell region CR and the boundary region BR. Accordingly, in the planarization process performed when forming the conductive line, the step that occurs due to the difference in etch rate due to the different layer materials between the cell region CR and the peripheral region PR may be reduced.

Accordingly, the semiconductor device capable of minimizing the defects due to the manufacturing process and have the improved electrical characteristics and the method of manufacturing the same may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a substrate including a cell region, a peripheral region, and a boundary region therebetween;
a first lower insulating layer disposed on the cell region and extending onto the boundary region and the peripheral region;
a second lower insulating layer disposed on the first lower insulating layer on the cell region and extending onto the first lower insulating layer on the boundary region and the peripheral region;
data storage patterns disposed on the second lower insulating layer on the cell region;
a cell insulating layer disposed on the second lower insulating layer on the cell region and the boundary region and covering the data storage patterns;
a peripheral insulating layer disposed on the second lower insulating layer on the peripheral region and including a material different from that of the cell insulating layer; and
a buffer insulating layer disposed on the cell insulating layer on the boundary region.

2. The semiconductor device of claim 1, further comprising an upper insulating layer interposed between the cell insulating layer and the buffer insulating layer on the boundary region and extending onto the cell insulating layer on the cell region.

3. The semiconductor device of claim 2, wherein the upper insulating layer on the boundary region has an upper surface recessed toward the substrate, and
wherein the recessed upper surface of the upper insulating layer on the boundary region is positioned at a lower height than an uppermost surface of the upper insulating layer on the cell region.

4. The semiconductor device of claim 3, wherein the uppermost surface of the upper insulating layer on the cell region is positioned at the same height as an upper surface of the buffer insulating layer on the boundary region.

5. The semiconductor device of claim 3, further comprising lower electrode contacts penetrating the first lower insulating layer and the second lower insulating layer on the cell region and connected to the data storage patterns, respectively; and
wiring lines disposed between the substrate and the first lower insulating layer,
wherein the lower electrode contacts penetrate the first lower insulating layer and are connected to the wiring lines.

6. The semiconductor device of claim 2, further comprising first cell conductive lines respectively disposed on the data storage patterns in the cell region and penetrating the upper insulating layer and the cell insulating layer on the cell region,
wherein the first cell conductive lines are connected to the data storage patterns, respectively.

7. The semiconductor device of claim 6, further comprising a peripheral conductive line penetrating an upper portion of the peripheral insulating layer,
wherein a difference between a height of an upper surface of the peripheral conductive line and a height of upper surfaces of the first cell conductive lines is within 15 nm.

8. The semiconductor device of claim 2, wherein the second lower insulating layer on the cell region has an upper surface recessed toward the substrate between the data storage patterns,
wherein the second lower insulating layer on the boundary region has an upper surface that is recessed toward the substrate, and
wherein the recessed upper surface of the second lower insulating layer on the boundary region is positioned at a lower height than the recessed upper surface of the second lower insulating layer on the cell region.

9. The semiconductor device of claim 8, further comprising lower electrode contacts disposed in the second lower insulating layer on the cell region and connected to the data storage patterns, respectively,
wherein an upper surface of the second lower insulating layer on the cell region is positioned at the same height as upper surfaces of the lower electrode contacts.

10. The semiconductor device of claim 2, wherein the buffer insulating layer extends onto the peripheral insulating layer on the peripheral region.

11. The semiconductor device of claim 10, further comprising:
first cell conductive lines respectively disposed on the data storage patterns in the cell region, penetrating the upper insulating layer and the cell insulating layer on the cell region, and respectively connected to the data storage patterns; and
a peripheral conductive line penetrating the buffer insulating layer on the peripheral region and penetrating an upper portion of the peripheral insulating layer,
wherein a difference between a height of an upper surface of the peripheral conductive line and a height of upper surfaces of the first cell conductive lines is within 15 nm.

12. The semiconductor device of claim 10, wherein the upper insulating layer on the boundary region has an upper surface recessed toward the substrate,
wherein the recessed upper surface of the upper insulating layer on the boundary region is positioned at a lower height than an uppermost surface of the upper insulating layer on the cell region.

13. The semiconductor device of claim 12, wherein the uppermost surface of the upper insulating layer on the cell region is positioned at the same height as an upper surface of the buffer insulating layer on the boundary region.

14. The semiconductor device of claim 13, wherein the upper surface of the buffer insulating layer on the boundary region is positioned at the same height as an upper surface of the buffer insulating layer on the peripheral region.

15. A semiconductor device comprising:
a substrate including a cell region, a peripheral region, and a boundary region therebetween;
a first lower insulating layer disposed on the cell region and extending onto the peripheral region;
a second lower insulating layer disposed on the first lower insulating layer on the cell region and extending onto the first lower insulating layer on the boundary region and the peripheral region;
data storage patterns disposed on the second lower insulating layer on the cell region;
lower electrode contacts penetrating the first lower insulating layer and the second lower insulating layer on the cell region and connected to the data storage patterns, respectively;
a cell insulating layer disposed on the second lower insulating layer on the cell region and the boundary region and covering the data storage patterns;
a peripheral insulating layer disposed on the second lower insulating layer on the peripheral region and including a material different from that of the cell insulating layer;
a peripheral conductive contact disposed in the peripheral insulating layer and penetrating the first lower insulating layer and the second lower insulating layer on the peripheral region; and
a buffer insulating layer disposed on the cell insulating layer on the boundary region.

16. The semiconductor device of claim 15, further comprising an upper insulating layer interposed between the cell insulating layer and the buffer insulating layer on the boundary region and extending onto the cell insulating layer on the cell region,
wherein the upper insulating layer on the boundary region has an upper surface recessed toward the substrate, and
wherein the recessed upper surface of the upper insulating layer on the boundary region is positioned at a lower height than an uppermost surface of the upper insulating layer on the cell region.

17. The semiconductor device of claim 16, wherein the uppermost surface of the upper insulating layer on the cell region is positioned at the same height as an upper surface of the buffer insulating layer on the boundary region.

18. The semiconductor device of claim 17, further comprising:
first cell conductive lines respectively disposed on the data storage patterns on the cell region and penetrating the upper insulating layer and the cell insulating layer on the cell region, and respectively connected to the data storage patterns; and
a peripheral conductive line penetrating an upper portion of the peripheral insulating layer,
wherein a difference between a height of an upper surface of the peripheral conductive line and a height of upper surfaces of the first cell conductive lines is within 15 nm.

19. The semiconductor device of claim 16, wherein the buffer insulating layer extends onto the peripheral insulating layer on the peripheral region, and
wherein an upper surface of the buffer insulating layer on the boundary region is positioned at the same height as an upper surface of the buffer insulating layer on the peripheral region.

20. The semiconductor device of claim 19, further comprising:
first cell conductive lines respectively disposed on the data storage patterns on the cell region, penetrating the upper insulating layer and the cell insulating layer on the cell region, and respectively connected to the data storage patterns; and
a peripheral conductive line penetrating the buffer insulating layer on the peripheral region and an upper portion of the peripheral insulating layer,
wherein a difference between a height of an upper surface of the peripheral conductive line and a height of upper surfaces of the first cell conductive lines is within 15 nm.
